(19) United States
(12) Patent Application Publication
(10) Pub. No.: US 2012/0064259 A1
(43) Pub. Date: Mar. 15, 2012

(54) ROTARY MAGNET SPUTTERING APPARATUS

(75) Inventors: Tadahiro Ohmi, Sendai-shi, Miyagi (JP); Tetsuya Goto, Miyagi (JP); Takaaki Matsuoka, Tokyo (JP)

(73) Assignees: TOKYO ELECTRON LIMITED, Tokyo (JP); TOHOKU UNIVERSITY, Sendai City, Miyagi (JP)

(21) Appl. No.: 13/320,376

(22) PCT Filed: Mar. 19, 2010
(86) PCT No.: PCT/JP2010/054867

§ 371 Date: Dec. 1, 2011

(30) Foreign Application Priority Data
May 15, 2009 (JP) 2009-118169

(51) Int. Cl. C23C 14/35; F28D 15/00

(52) U.S. Cl. 427/571; 165/185; 118/723 R

(57) ABSTRACT

Provided is a rotary magnet sputtering apparatus that reduces an adverse effect due to heating of a target portion and so on caused by an increase in plasma excitation power. The rotary magnet sputtering apparatus has a structure in which the heat is removed from the target portion by causing a cooling medium to flow in helical spaces formed between a plurality of helical plate-like magnet groups or by providing a cooling passage in a backing plate which supports the target portion.

### TECHNICAL FIELD

This invention relates to a sputtering apparatus widely used in forming a film of metal or insulator and, in particular, relates to a magnetron sputtering apparatus using a rotary magnet, which is a processing apparatus for applying a predetermined surface treatment to a workpiece such as a liquid crystal display substrate or a semiconductor substrate.

### BACKGROUND ART

Sputtering apparatuses are widely used in the manufacture of optical disks, in the manufacture of electronic devices such as liquid crystal display elements and semiconductor elements, and further, in the formation of metal thin films and insulator thin films in general. In the sputtering apparatus, a raw material for thin film formation is used as a target, an argon gas or the like is converted into plasma by DC high voltage or high-frequency power, and the target is activated by the plasma-converted gas so that the target is melted and scattered to be coated on a substrate to be processed.

As a sputtering film forming method, a predominant film forming method uses a magnetron sputtering apparatus in which, in order to raise the film forming rate, magnets are disposed on the back side of a target to generate the lines of magnetic force parallel to a target surface, thereby confining plasma to the target surface to obtain high-density plasma.

For the purpose of improving the target utilization efficiency to reduce the production cost and enabling the stable long-term operation, the present inventors have previously proposed a rotary magnet sputtering apparatus. This is a remarkable sputtering apparatus which is configured such that a plurality of plate-like magnets are continuously disposed on a columnar rotary shaft and, by rotating them, a magnetic field pattern on a target surface moves with time, thereby not only significantly improving the utilization efficiency of a target material, but also preventing charge-up damage and ion irradiation damage due to plasma (see Patent Document 1).

### PRIOR ART DOCUMENT

### Patent Document

Patent Document 1: WO2007/043476

### SUMMARY OF THE INVENTION

### Problem to be Solved by the Invention

In general, in a magnetron sputtering method, in order to raise the film forming rate to improve the throughput, it is effective to increase the plasma excitation power. In this event, when the plasma excitation power is increased, the plasma heat flow increases so that it is not possible to prevent a target and a backing plate supporting the target from rising to a high temperature. As a consequence, there is a possibility that an indium layer bonding the target to the backing plate is melted to cause detachment of the target or that deformation or the like of the backing plate occurs.

Also in the sputtering apparatus shown in Patent Document 1, the necessity for cooling a target and so on is taken into account so that a coolant passage is provided at an end portion of a backing plate (outside its portion holding the target). However, a further improvement of the cooling mechanism is preferable in terms of efficient cooling.

It is an object of this invention to provide a sputtering apparatus that can efficiently cool a target and a backing plate to thereby deal with an increase in plasma excitation power.

Further, it is an object of this invention to provide a sputtering apparatus that can perform efficient cooling by selecting a position where a cooling medium flows.

### Means for Solving the Problem

According to a first aspect of this invention, there is provided a rotary magnet sputtering apparatus comprising a substrate placing stage for placing thereon a substrate to be processed, a backing plate on which a target is to be fixedly placed so as to face the substrate, and a magnet disposed on a side opposite to the substrate placing stage with respect to a portion where the target is placed, and adapted to confine plasma on a target surface by forming a magnetic field on the target surface using the magnet, the rotary magnet sputtering apparatus characterized in that the magnet comprises a rotary magnet group having a plurality of plate-like magnets on a columnar rotary shaft and a fixed outer peripheral plate-like magnet or a fixed outer peripheral ferromagnetic member which is arranged in parallel to the target surface around the rotary magnet group, the magnet is structured so that a magnetic field pattern on the target surface moves with time by rotating the rotary magnet group along with the columnar rotary shaft, and a passage for causing a cooling medium to flow therein is provided between the rotary magnet group and the backing plate.

According to another aspect of this invention, there is provided the rotary magnet sputtering apparatus according to the above described aspect, characterized in that the rotary magnet group forms one or a plurality of helical plate-like magnet groups by helically bonding the plate-like magnets to the columnar rotary shaft with either an N-pole or an S-pole directed toward the outer side in a diameter direction of the columnar rotary shaft.

According to another aspect of this invention, there is provided the rotary magnet sputtering apparatus according to any one of the above described aspects, characterized in that the even-numbered helical plate-like magnet groups are provided on the columnar rotary shaft such that helices adjacent to each other in an axial direction of the columnar rotary shaft form mutually different magnetic poles, i.e. an N-pole and an S-pole, on the outer side in a diameter direction of the columnar rotary shaft.

According to another aspect of this invention, there is provided the rotary magnet sputtering apparatus according to any one of the above described aspects, characterized in that the fixed outer peripheral plate-like magnet or the fixed outer peripheral ferromagnetic member is a magnet which is configured to surround the rotary magnet group as seen from the target side and which forms one of an N-pole and an S-pole on the target side.

According to another aspect of this invention, there is provided the rotary magnet sputtering apparatus according to any one of the above-described aspects, characterized in that the passage is formed so that the cooling medium flows helically in a space between the plurality of helical plate-like magnet groups.

According to another aspect of this invention, there is provided the rotary magnet sputtering apparatus according to any one of the above-described aspects, characterized in that the cooling medium is caused to flow by setting the Reynolds number thereof to 1000 to 5000.

According to another aspect of this invention, there is provided the rotary magnet sputtering apparatus according to any one of the above described aspects, characterized in that the passage includes a space surrounded by side walls of the helical plate-like magnet groups, the columnar rotary shaft, and a shielding plate disposed outside the helical plate-like magnet groups and the cooling medium flows helically along the helical plate-like magnet groups. According to another aspect of this invention, there is provided the rotary magnet sputtering apparatus according to any one of the above-described aspects, characterized in that at least part of the shielding plate is a ferromagnetic member.

According to another aspect of this invention, there is provided a sputtering method characterized by using the rotary magnet sputtering apparatus according to any one of the above described aspects and forming a film of a material of the target on the substrate while rotating the columnar rotary shaft.

According to another aspect of this invention, there is provided a method of manufacturing an electronic device, characterized by comprising a step of carrying out sputtering film formation on the substrate using the sputtering method according to the above-described aspect.

### Effect of the Invention

According to this invention, in a rotary magnet sputtering apparatus, it is possible to improve the cooling efficiency and thus to increase the allowable power application amount for plasma excitation, thereby realizing an improvement in film forming rate and throughput.

### BRIEF DESCRIPTION OF THE DRAWINGS

FIG. 1 is a schematic structural view showing a cooling device of a rotary magnet sputtering apparatus according to a first embodiment of this invention.

FIG. 2 is a schematic structural view showing a rotary magnet sputtering apparatus according to a second embodiment of this invention.

FIG. 3 is a perspective view for explaining in more detail a magnet portion of the rotary magnet sputtering apparatus shown in FIG. 2.

FIG. 4 is a view for explaining plasma loop formation in the rotary magnet sputtering apparatus shown in FIG. 2.

FIG. 5 is a top view of a backing plate for explaining in more detail a cooling water passage of the rotary magnet sputtering apparatus shown in FIG. 1.

FIG. 6 is a side (partially sectioned) view for explaining in more detail cooling water passages of the rotary magnet sputtering apparatus shown in FIG. 2.

### MODE FOR CARRYING OUT THE INVENTION

Hereinbelow, embodiments of this invention will be described with reference to the drawings.

### First Embodiment

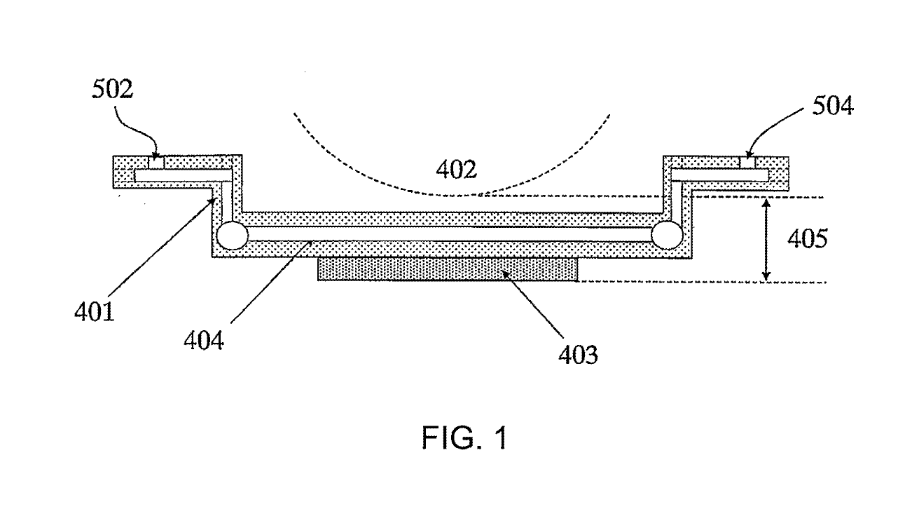

Referring to FIG. 1, a cooling mechanism in a rotary magnet sputtering apparatus according to a first embodiment of this invention will be described. Herein, only a portion related to the cooling mechanism of the rotary magnet sputtering apparatus is schematically illustrated.

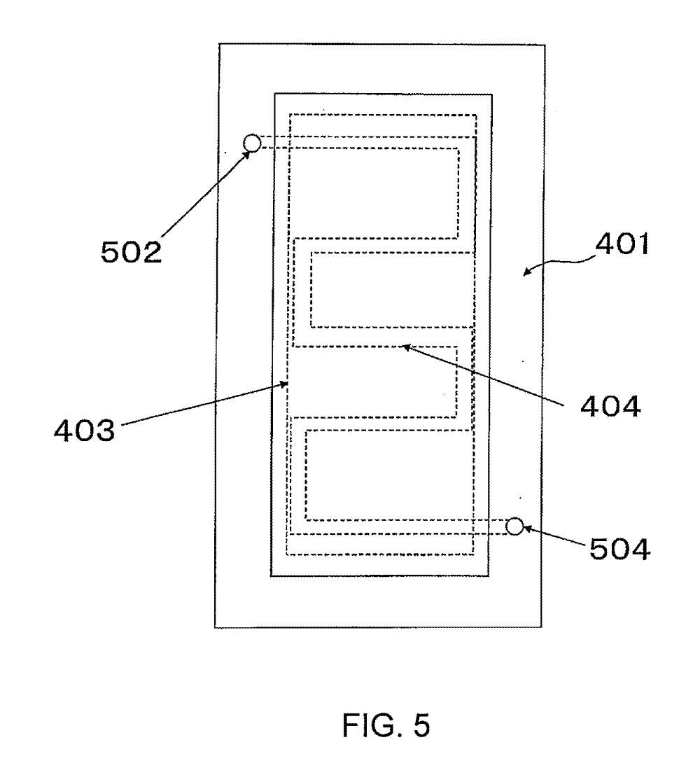

In FIG. 1, 401 denotes a backing plate, 402 a rotary magnet, 403 a target portion, and 404 a cooling water passage. In this embodiment, the cooling water passage 404 forming the cooling mechanism is provided in the backing plate 401 at its portion overlapping the target portion 403. As illustrated, the target portion 403 is attached to one surface of the backing plate 401 and the rotary magnet 402 is provided on the opposite side of the backing plate 401 with respect to its surface where the target portion 403 is attached. FIG. 5 is a view seen from above of the backing plate. The cooling water passage 404 is provided so as to overlap the target portion 403. 502 denotes a cooling water inlet and 504 a cooling water outlet. By providing the cooling water passage right above the target as described above, it is possible to enhance the cooling efficiency. As will be described later, the rotary magnet 402 has a structure in which a plurality of helical plate-like magnet groups are attached on a columnar rotary shaft so that, by rotating the rotary magnet 402, closed plasma regions are continuously formed on the target portion 403 between the rotary magnet 402 and a fixed ferromagnetic portion disposed around the rotary magnet 402 and that these plasma regions move along the columnar rotary shaft along with the rotation of the rotary magnet 402. Accordingly, the rotary magnet sputtering apparatus of this structure has an advantage that the target portion 403 can be effectively used.

On the other hand, when the plasma excitation power is increased in order to raise the film forming rate to improve the throughput, the plasma heat flow increases.

The heat flow from plasma is greatest at the target portion 403 where plasma excitation is performed. Therefore, in this embodiment, in order to enhance the cooling efficiency, the cooling water passage 404 is provided as the cooling mechanism in the backing plate 401 adjacent to the target portion 403.

Since, as described above, the cooling water passage 404 is provided adjacent to the contact surface with the target portion 403, the cooling can be efficiently carried out.

In this case, the cooling water passage 404 is preferably as close to the target portion 403 as possible. Accordingly, the backing plate 401 should be relatively thick.

On the other hand, in order to improve the plasma excitation efficiency, it is necessary to increase the magnetic field strength on a surface of the target portion 403. The horizontal magnetic field strength (component, in a direction parallel to the target surface, of the magnetic field strength) in a plasma loop is preferably set to 500 gauss or more.

For this, the distance (T/S distance) 405 between the rotary magnet 402 and the surface of the target portion 403 shown in FIG. 1 is preferably set to 30 mm or less and desirably 20 mm or less.

Actually, when the cooling water passage 404 is provided in the backing plate 401 while setting the T/S distance to 20 mm, the thickness of the backing plate 401 is set to 12 mm and the backing plate 401 and the rotary magnet 402 are spaced apart from each other by 1 mm so as to prevent contact therebetween. In this case, it has been found that the thickness of the target portion 403 is preferably set to about 7 mm.

Herein, the target portion 403 and the backing plate 401 are bonded to each other by an indium layer. It has been confirmed that deformation of the backing plate 401 and so on can be prevented with the structure of FIG. 1 in which the cooling water passage 404 is provided in the backing plate 401.

As described above, according to the first embodiment, since the cooling water passage 404 is provided in the backing plate 401, it is possible to prevent deformation of the backing plate 401 and detachment of the target layer 403, which are otherwise caused by the increase in plasma heat flow.

Next, a second embodiment of this invention will be described in detail with reference to the drawings.

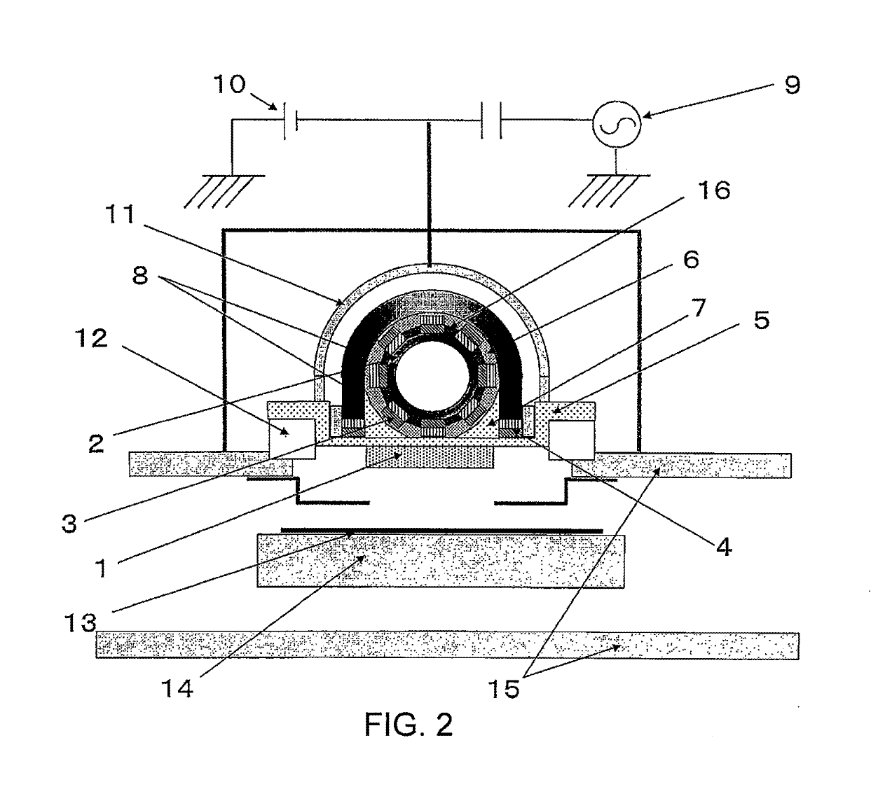

Referring to FIG. 2, the structure of a rotary magnet sputtering apparatus according to the second embodiment of this invention is shown.

In FIG. 2, 1 denotes a target, 2 a columnar rotary shaft, 3 a plurality of helical plate-like magnet groups helically disposed on a surface of the rotary shaft 2, 4 a fixed outer peripheral plate-like magnet or a fixed outer peripheral ferromagnetic member disposed around the helical plate-like magnet groups 3 (hereinbelow, a description will be given assuming that it is the fixed outer peripheral plate-like magnet), 5 a backing plate to which the target 1 is bonded, 6 a cooling medium (cooling water in this embodiment) for heat removal of the heat flow from plasma, 7 a first shielding plate for forming cooling water passages, 8 a second shielding plate for forming the cooling water passages, 16 a plate for adjusting the cross-sectional area of the cooling water passages, 9 an RF power supply for plasma excitation, 10 a DC power supply for plasma excitation and target DC voltage control, 11 an aluminum shielding plate for supplying the power to the backing plate and the target, 12 an insulating member, 13 a substrate to be processed, 14 a placing stage for placing thereon a substrate to be processed, and 15 outer walls (e.g. made of aluminum or aluminum alloy) forming a process chamber.

The power frequency of the RF power supply 9 is 13.56 MHz. Although this embodiment employs an RF-DC coupled discharge system which also enables superimposed application by the DC power supply, sputtering may be DC discharge sputtering only by the DC power supply or RF discharge sputtering only by the RF power supply.

A material of the columnar rotary shaft 2 may be an ordinary stainless steel or the like, but it is preferable that the columnar rotary shaft 2 be partly or entirely made of a ferromagnetic substance with a low magnetic resistance such as, for example, a Ni—Fe-based high magnetic permeability alloy or iron. In this embodiment, the columnar rotary shaft 2 is made of the iron. The columnar rotary shaft 2 can be rotated by a non-illustrated gear unit and motor.

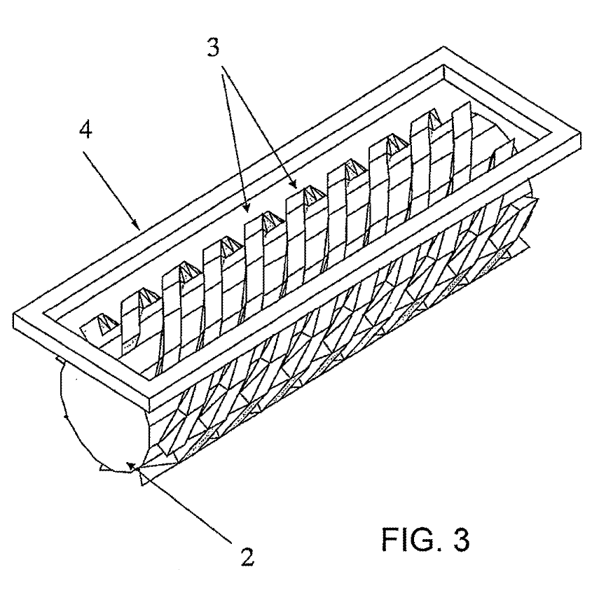

Referring to FIG. 3, the helical plate-like magnet groups 3 and the fixed outer peripheral magnet 4 shown in FIG. 2 will be described in more detail. The columnar rotary shaft 2 has a regular hexadecagonal cross-section with one side having a length of 18 mm. Many rhombic plate-like magnets are attached to respective faces thereof and the plurality of helical plate-like magnet groups 3 rotate along with the rotation of the columnar rotary shaft 2. Therefore, the helical plate-like magnet groups 3 form, namely, rotary magnets. Helical spaces are present between the plurality of helical plate-like magnet groups 3.

The columnar rotary shaft 2 is configured so as to be attached with the magnets on its outer periphery, can be easily made thick, and has a structure that is strong against bending deformation due to magnetic forces applied by the magnets. In order to stably generate a strong magnetic field, each of the plate-like magnets forming the helical plate-like magnet groups 3 is preferably a magnet with a high residual magnetic flux density, a high coercive force, and a high energy product, such as, for example, a Sm—Co-based sintered magnet with a residual magnetic flux density of about 1.1 T or a Nd—Fe—B-based sintered magnet with a residual magnetic flux density of about 1.3 T. In this embodiment, the Nd—Fe—B-based sintered magnet is used. The plate-like magnets of the helical plate-like magnet groups 3 are each magnetized in a direction perpendicular to its plate surface and are helically bonded to the columnar rotary shaft 2 to form a plurality of helices such that the helices adjacent to each other in an axial direction of the columnar rotary shaft form mutually different magnetic poles, i.e. N-poles and S-poles, on the outer side in a diameter direction of the columnar rotary shaft.

When the fixed outer peripheral plate-like magnet 4 is seen from the target 1, it is configured to surround a rotary magnet group composed of the helical plate-like magnet groups 3. Further, the fixed outer peripheral plate-like magnet 4 is magnetized so that the target 2 side thereof becomes an S-pole. An Nd—Fe—B-based sintered magnet is used also as the fixed outer peripheral plate-like magnet 4 for the same reason as for the plate-like magnets of the helical plate-like magnet groups 3.

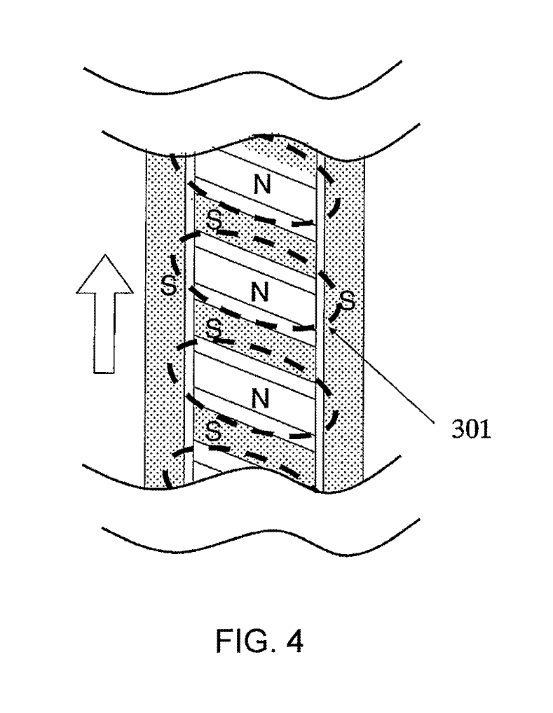

Next, referring to FIG. 4, a description will be given in detail about plasma formation in this embodiment. As described above, the helical plate-like magnet groups 3 are formed by disposing the many plate-like magnets on the columnar rotary shaft 2. In this case, when the helical plate-like magnet groups 3 are seen from the target side, an arrangement is given such that the N-poles of the plate-like magnets are approximately surrounded by the S-poles of the other plate-like magnets. FIG. 3 is a conceptual diagram thereof. With this configuration, the lines of magnetic force generated from the N-poles of the helical plate-like magnet groups 3 are terminated at the peripheral S-poles. As a result, many closed plasma regions 301 are formed on the target 1 surface located at some distance from surfaces of the plate-like magnets. Further, by rotating the columnar rotary shaft 2, the many plasma regions 301 move along with the rotation. In FIG. 4, the plasma regions 301 move in a direction indicated by an arrow. At end portions of the helical plate-like magnet groups 3, the plasma regions 301 sequentially appear from one of the end portions and sequentially disappear at the other end portion.

In the above-mentioned example, the surface of one of the helical plate-like magnet groups 3 has the N-pole while the surfaces of the other helical plate-like magnet groups 3 adjacent to such one of the helical plate-like magnet groups 3 and the surface of the fixed magnet 4 around the helical plate-like magnet groups 3 have the S-poles so that the S-poles are arranged to surround in a loop the N-pole of the surface of the first helix, but the N- and S-poles may be reversed. Even if a ferromagnetic member, i.e. not a magnet magnetized in advance, is used instead of each of the plate-like magnets of the other helical plate-like magnet groups 3 adjacent to such one of the helical plate-like magnet groups 3 and/or instead of the fixed magnet around the rotary magnets, a loop-shaped planar magnetic field surrounding in a loop the N-pole (or the S-pole) of the surface of the first helix is obtained and, as a result, loop-shaped plasma is obtained.

The placing stage 14 with the substrate 13 placed thereon has a moving mechanism adapted to pass under the target 1 and thus causes the substrate 13 to move thereto while plasma is excited on the target surface, thereby allowing film formation to be carried out (see FIG. 2).

Referring back to FIG. 2, the helical plate-like magnet groups 3 and the columnar rotary shaft 2 included in the rotary magnet sputtering apparatus according to the second embodiment of this invention are surrounded by the first shielding plate 7 made of copper and the second shielding plate 8 made of iron being a ferromagnetic substance and the cooling water 6 is configured to flow in surrounded spaces. That is, a cooling mechanism according to this embodiment is provided so as to surround the helical plate-like magnet groups 3 attached on the columnar rotary shaft 2 and, in the case of this example, the cooling mechanism is formed by the first shielding plate 7 provided in contact with the backing plate 5 and the second shielding plate 8 provided at a position spaced apart from the backing plate 5 and joined to the first shielding plate 7. Although the first shielding plate 7 is formed of copper being a nonmagnetic substance while the second shielding plate 8 is formed of iron being a ferromagnetic substance, the second shielding plate 8 may also be formed of a nonmagnetic substance or a paramagnetic substance.

As described above, by surrounding the outside of the helical plate-like magnet groups 3 with the cooling mechanism formed by the first and second shielding plates 7 and 8, it is possible to form helical passages between side walls of the helical plate-like magnet groups 3 (i.e. spaces between the helical plate-like magnet groups 3) and the columnar rotary shaft 2.

In the illustrated embodiment, by causing the cooling water 6 to flow in the passages defined by the helical spaces, it is possible to cool the backing plate 5 and the target portion 1. In this case, the cooling water 6 flows helically along the helical spaces between the helical plate-like magnet groups 3.

As described above, with the configuration that the cooling water 6 is caused to flow in the passages defined by the helical spaces, as compared with the case where the cooling water passage is provided in the backing plate 5 as in the first embodiment, the cooling water passages can be provided over a wider area so that it is possible to further enhance the cooling efficiency. As a consequence, the film forming rate can be increased as compared with the first embodiment.

Further, using the cooling mechanism of this invention, it is not necessary to provide the cooling water passage in the backing plate 5 as in the first embodiment. Therefore, the backing plate 5 can be reduced in thickness as compared with the first embodiment and, further, the strength of the backing plate 5 can be increased as compared with the case where the cooling water passage is provided therein.

Further, since the backing plate 5 can be reduced in thickness, the target 1 can be increased in thickness as compared with the first embodiment so that it is possible to reduce the replacement frequency of a target as compared with the first embodiment and thus to improve the production efficiency. In this case, the thickness of the backing plate 5 can be reduced to about 5 mm and, as a result, the thickness of the target 1 can be increased to 14 mm.

However, if the plasma excitation power further increases to require further cooling, the above-mentioned cooling mechanism and the structure in which the cooling water passage is provided in the backing plate 5 may be used jointly.

In order to ensure heat conduction, the copper first shielding plate 7 and the backing plate 5 should be in tight contact with each other. The second shielding plate 8 is formed of iron being a ferromagnetic substance and thus also serves to form a magnetic circuit between the fixed outer peripheral magnet 4 and the rotary magnet portion so that it is possible to form a strong magnetic field on the target surface. Since the first shielding plate 7 is located at the position close to the target 1, if the first shielding plate 7 is formed of a ferromagnetic substance, it is not possible to form a strong magnetic field on the target 1 surface and, therefore, use is made of copper which is a material being not a ferromagnetic substance and is excellent in heat conduction.

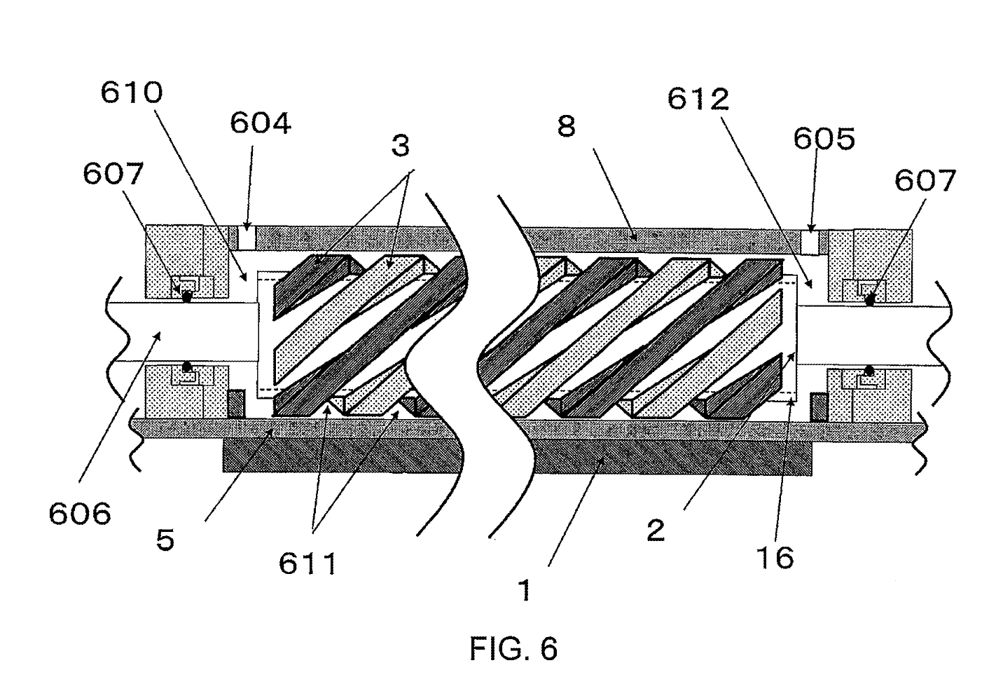

FIG. 6 shows a longitudinal sectional view (partially sectioned side view) in a plane including an axis of the rotary magnet, in the cooling structure according to the second embodiment of this invention. The rotary magnet has the structure in which the helical plate-like magnet groups 3 are attached on the columnar rotary shaft 2. The backing plate 5 is disposed close to the rotary magnet surface and the target 1 is bonded on the opposite side thereof. 604 denotes a cooling water inlet, 605 a cooling water outlet, 606 a shaft for rotating the columnar rotary shaft 2, 607 O-ring shaft seals, 16 the plate attached to the helical magnet side walls for adjusting the cross-sectional area of the passages, and 8 the shielding plate. In order to seal the cooling water, the rotary portion uses the O-ring shaft seals 607 to prevent leakage of the cooling water to the outside and, further, the shielding plate 8 and so on are also suitably attached through O-ring seals (illustration omitted). The cooling water introduced from the cooling water inlet 604 is first introduced into a space 610 at a rotary magnet end portion and then is supplied into cooling water passages 611 formed by the helical magnet side walls, the shielding plates, etc. and performs cooling. Then, the cooling water is introduced into a space 612 at the other rotary magnet end portion and then is discharged from the cooling water outlet 605. Even in the state where the rotary shaft is not rotated, the cooling water in the cooling water passages 611 flows helically between the rotary magnets to form turbulent flows, thereby enhancing the cooling effect. However, when the rotary magnets are rotated, the cooling water is stirred more violently so that the cooling efficiency is further enhanced.

In order to seal the cooling water 6, the shielding plate 7 is also attached through O-ring seals. The columnar rotary shaft 2 also uses the O-ring shaft seals 607, thereby preventing leakage of the cooling water 6 to the outside.

It is preferable to cause the cooling water 6 to flow substantially between the helical plate-like magnet groups 3 by providing the first and second shielding plates 7 and 8 as close to the helical plate-like magnet groups 3 as possible. With this configuration, since the cooling water 6 flows helically along the helical plate-like magnet groups 3, the cooling water 6 whose temperature is raised by cooling the target 1 in the vicinity of the backing plate 5 is rapidly transported to the side opposite to the backing plate 5 so that the heat is removed quite efficiently.

Further, in order to maximize the cooling efficiency in the cooling mechanism according to this invention, it is important to take into account the Reynolds number of the cooling water. The Reynolds number Re is defined by Re=V×d/v. Herein, V is the velocity of a fluid (herein, cooling water), d the pipe diameter, and v the coefficient of kinematic viscosity. The Reynolds number which is also used as an index for distinguishing between a turbulent flow and a laminar flow and which is obtained when the flow velocity increases so that a laminar flow transitions to a turbulent flow is called the critical Reynolds number. In the case of the flow in a circular pipe, the critical Reynolds number is 2,000 to 4,000. In general, the cooling efficiency is low when the flow velocity is small to form a laminar flow, while the cooling efficiency is improved when the flow velocity increases to reach a turbulent flow region. However, even if the flow velocity increases more than that, although the cooling efficiency is enhanced slightly, the pressure loss of the cooling water increases so that the energy for causing the cooling water to flow increases, which is thus not preferable. As a result, the cooling is enabled most efficiently when the cooling water flows at a flow velocity close to the critical Reynolds number. That is, it is preferable to set the Reynolds number to 1000 to 5000 and desirably 2000 to 4000. In this embodiment, in order to control the Reynolds number, the plate for adjusting the cross-sectional area of the cooling water passages is disposed at the helical magnet side walls as indicated by 16 in FIGS. 2 and 6, thereby setting the cross-sectional area of the passage to 72 mm² (equivalent diameter 9.6 mm). Since the number of the cooling water passages is eight, the flow velocity is set to 0.29 m/s and the Reynolds number to about 2800 when the cooling water is caused to flow at 10 liters per minute (coefficient of kinematic viscosity of water is about 10⁻⁶ m²/s). As a result of improving the cooling efficiency as described above, while the maximum power density that can be applied to the target portion 1 is about 5 W/cm² in cooling with a conventional system, it is possible to apply 10 W/cm² or more.

While this invention has been described with reference to the embodiments, various settings such as the cooling water amount are not limited to the embodiments.

### INDUSTRIAL APPLICABILITY

A magnetron sputtering apparatus according to this invention can be not only used for forming an insulating film or a conductive film on a semiconductor wafer or the like, but also applied for forming various films on a substrate such as a glass substrate of a flat display device, and can be used for sputtering film formation in the manufacture of storage devices or other electronic devices.

### DESCRIPTION OF SYMBOLS

1 target
2 columnar rotary shaft
3 helical plate-like magnet group
4 fixed outer peripheral plate-like magnet
5 backing plate
6 cooling medium
7, 8 shielding plates forming cooling medium passages
9 RF power supply
10 DC power supply
11 process chamber space
12 insulating member
13 substrate to be processed
14 placing stage
15 process chamber outer wall

What is claimed is:

1. A rotary magnet sputtering apparatus comprising a substrate placing stage for placing thereon a substrate to be processed, a backing plate on which a target is to be fixedly placed so as to face the substrate, and a magnet disposed on a side opposite to the substrate placing stage with respect to a portion where the target is placed, and adapted to confine plasma on a target surface by forming a magnetic field on the target surface using the magnet, the rotary magnet sputtering apparatus wherein
the magnet comprises a rotary magnet group having a plurality of plate-like magnets on a columnar rotary shaft and a fixed outer peripheral plate-like magnet or a fixed outer peripheral ferromagnetic member which is arranged in parallel to the target surface around the rotary magnet group,
the magnet is structured so that a magnetic field pattern on the target surface moves with time by rotating the rotary magnet group along with the columnar rotary shaft, and
a passage for causing a cooling medium to flow therein is provided between the rotary magnet group and the backing plate.

2. The rotary magnet sputtering apparatus according to claim 1, wherein the rotary magnet group forms one or a plurality of helical plate-like magnet groups by helically bonding the plate-like magnets to the columnar rotary shaft with either an N-pole or an S-pole directed toward the outer side in a diameter direction of the columnar rotary shaft.

3. The rotary magnet sputtering apparatus according to claim 2, wherein the even-numbered helical plate-like magnet groups are provided on the columnar rotary shaft such that helices adjacent to each other in an axial direction of the columnar rotary shaft form mutually different magnetic poles, i.e. an N-pole and an S-pole, on the outer side in a diameter direction of the columnar rotary shaft.

4. The rotary magnet sputtering apparatus according to claim 1, wherein the fixed outer peripheral plate-like magnet or the fixed outer peripheral ferromagnetic member is a magnet which is configured to surround the rotary magnet group as seen from the target side and which forms one of an N-pole and an S-pole on the target side.

5. The rotary magnet sputtering apparatus according to claim 2, wherein the passage is formed so that the cooling medium flows helically in a space between the plurality of helical plate-like magnet groups.

6. The rotary magnet sputtering apparatus according to claim 1, wherein the cooling medium is caused to flow by setting the Reynolds number thereof to 1000 to 5000.

7. The rotary magnet sputtering apparatus according to claim 2, wherein the passage includes a space surrounded by side walls of the helical plate-like magnet groups, the columnar rotary shaft, and a shielding plate disposed outside the helical plate-like magnet groups and the cooling medium flows helically along the helical plate-like magnet groups.

8. The rotary magnet sputtering apparatus according to claim 7, wherein at least part of the shielding plate is a ferromagnetic member.

9. A sputtering method using the rotary magnet sputtering apparatus according to claim 1 and forming a film of a material of the target on the substrate while rotating the columnar rotary shaft.

10. A method of manufacturing an electronic device, comprising a step of carrying out sputtering film formation on the substrate using the sputtering method according to claim 9.

11. A rotary magnet sputtering apparatus comprising a backing plate for supporting a target portion, a columnar rotary shaft provided on a side opposite to a surface, for supporting the target portion, of the backing plate, a plurality of helical plate-like magnet groups disposed on the columnar rotary shaft so as to form helical spaces therebetween, and a cooling mechanism for causing a cooling medium to flow in the helical spaces between the plurality of helical plate-like magnet groups.

12. The rotary magnet sputtering apparatus according to claim 11, wherein the cooling mechanism comprises a first shielding plate provided in contact with the backing plate and a second shielding plate provided so as to surround the plurality of helical plate-like magnet groups and joined to the first shielding plate.

13. The rotary magnet sputtering apparatus according to claim 12, wherein the first shielding plate is formed of a nonmagnetic substance while the second shielding plate is formed of a magnetic substance.

14. The rotary magnet sputtering apparatus according to claim 13, wherein the nonmagnetic substance of the first shielding plate is copper and the magnetic substance of the second shielding plate is iron.

15. A rotary magnet sputtering apparatus comprising a backing plate for supporting a target portion, a columnar rotary shaft provided on a side opposite to a surface, for supporting the target portion, of the backing plate, and a plurality of helical plate-like magnet groups disposed on the columnar rotary shaft so as to form helical spaces therebetween, wherein a cooling passage is provided at a portion, which overlaps the target portion as seen from the target portion, in the backing plate.

16. A method of cooling a rotary magnet sputtering apparatus having a plurality of helical plate-like magnet groups which are disposed on a columnar rotary shaft so as to form helical spaces therebetween, the method comprising forming, in advance, cooling medium passages so as to surround the helical spaces between the plurality of helical plate-like magnet groups and carrying out cooling by causing a cooling medium to flow in the cooling medium passages.
